(19) United States
(12) Patent Application Publication
(10) Pub. No.: US 2024/0055399 A1
(43) Pub. Date: Feb. 15, 2024

(54) SEMICONDUCTOR STRUCTURE, METHOD FOR MANUFACTURING SEMICONDUCTOR STRUCTURE, AND SEMICONDUCTOR DEVICE

(71) Applicant: CHANGXIN MEMORY TECHNOLOGIES, INC., Hefei City (CN)

(72) Inventors: Kaimin LV, Hefei (CN); Ling-Yi Chuang, Hefei (CN)

(21) Appl. No.: 18/446,512

(22) Filed: Aug. 9, 2023

Related U.S. Application Data
(63) Continuation of application No. PCT/CN2022/118540, filed on Sep. 13, 2022.

(30) Foreign Application Priority Data
Aug. 10, 2022 (CN) 202210957689.1

(51) Int. Cl. H01L 25/065; H01L 23/538; H10B 80/00; H01L 23/00; H01L 23/31; H01L 23/48; H01L 25/00

(52) U.S. Cl. CPC H01L 25/0655; H01L 23/5386; H10B 80/00; H01L 23/5384; H01L 24/48; H01L 23/3128; H01L 23/481; H01L 24/08; H01L 25/50; H01L 2224/48235; H01L 2224/08137

(57) ABSTRACT

A semiconductor structure, a method for manufacturing same, and a semiconductor device are provided. The semiconductor structure includes: a substrate having a groove and power supply pins; a storage module located in the groove; in which the storage module includes a plurality of storage chips stacked in a first direction, the first direction being parallel to the bottom surface of the groove; power supply signal lines being provided in each of the storage chips, and at least one of the plurality of storage chips having a power supply wiring layer electrically connected to the power supply signal lines; and conductive parts connected with the power supply wiring layer and the power supply pins.

### CROSS-REFERENCE TO RELATED APPLICATIONS

This application is a U.S. continuation application of International Application No. PCT/CN2022/118540, filed Sep. 13, 2022, which claims priority to Chinese Patent Application No. 202210957689.1, filed Aug. 10, 2022. International Application No. PCT/CN2022/118540 and Chinese Patent Application No. 202210957689.1 are incorporated herein by reference in their entireties.

### BACKGROUND

In order to improve the integration level of a semiconductor structure, more than one storage chip may be placed in a same package structure. A High Bandwidth Memory (HBM) is a novel memory. An original one-dimensional memory is expanded to a three-dimensional memory by means of a storage chip stacking technique represented by the HBM, i.e., a plurality of storage chips are stacked together and packaged, such that the density of the storage chips is greatly improved, and a large capacity and a high bit width are achieved.

However, as the number of stacked layers increases, the performance of the HBM is to be improved.

### SUMMARY

Embodiments of the disclosure belong to the field of semiconductors, and in particular relate to a semiconductor structure, a method for manufacturing the semiconductor structure, and a semiconductor device.

According to some embodiments of the disclosure, embodiments of the disclosure, on one hand, provide a semiconductor structure. The semiconductor structure includes: a substrate having a groove and power supply pins; a storage module located in the groove; in which the storage module includes a plurality of storage chips stacked in a first direction, the first direction being parallel to the bottom surface of the groove; power supply signal lines being provided in each of the storage chips, and at least one of the plurality of storage chips having a power supply wiring layer electrically connected to the power supply signal lines; and conductive parts connected with the power supply wiring layer and the power supply pins.

According to some embodiments of the disclosure, embodiments of the disclosure, on another hand, provide a method for manufacturing a semiconductor structure. The method includes that: a substrate is provided, the substrate having a groove and power supply pins; a storage module is provided, in which the storage module includes a plurality of storage chips stacked in a first direction, power supply signal lines being provided in each of the storage chips, and at least one of the plurality of storage chips having a power supply wiring layer electrically connected to the power supply signal lines; the storage module is placed in the groove, and the first direction is enabled to be parallel to the bottom surface of the groove; and the power supply wiring layer is connected with the power supply pins through conductive parts.

According to some embodiments of the disclosure, embodiments of the disclosure, on still another hand, provide a semiconductor device. The semiconductor device includes: a circuit board; a substrate having a groove and power supply pins, in which the substrate is disposed on the circuit board; a storage module located in the groove, in which the storage module includes a plurality of storage chips stacked in a first direction, the first direction being parallel to the bottom surface of the groove; power supply signal lines being provided in each of the storage chips, and at least one of the plurality of storage chips has a power supply wiring layer electrically connected to the power supply signal lines; and conductive parts connected with the power supply wiring layer and the power supply pins.

### BRIEF DESCRIPTION OF THE DRAWINGS

The accompanying drawings, which are incorporated in and constitute a part of this specification, illustrate the embodiments consistent with the present disclosure and, together with the specification, serve to explain the principles of the disclosure. It is apparent that the drawings described below are only some embodiments of the disclosure, and other drawings can further be obtained by those of ordinary skill in the art according to the drawings without creative work.

FIG. 1 illustrates a schematic diagram of a semiconductor structure.

FIG. 2, FIG. 5 and FIG. 7 respectively illustrate sectional views of different semiconductor structures provided by an embodiment of the disclosure.

FIG. 3, FIG. 6, and FIG. 8 respectively illustrate top views of different semiconductor structures provided by an embodiment of the disclosure.

FIG. 4, FIG. 9, and FIG. 10 respectively illustrate schematic diagrams of active surfaces of different storage chips provided by an embodiment of the disclosure.

FIGS. 11-12 illustrate schematic structural diagrams corresponding to steps in a method for manufacturing a semiconductor structure provided by another embodiment of the disclosure.

FIG. 13 illustrates a schematic diagram of a semiconductor device provided by still other embodiment of the disclosure.

### DETAILED DESCRIPTION

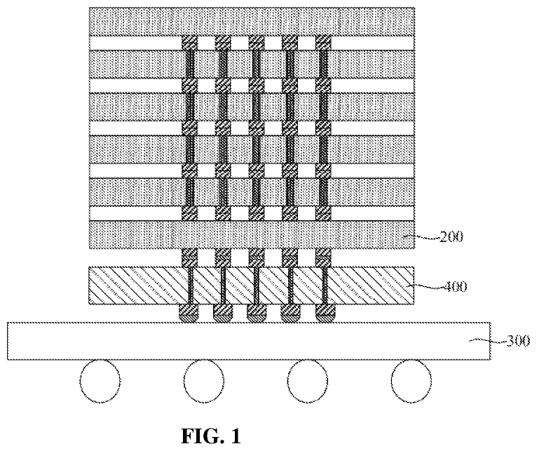

Referring to FIG. 1, the arrangement direction of a plurality of storage chips 200 of an HBM is perpendicular to the upper surface of the substrate 300. In a case where there are more stacked layers, there is a great difference between the communication di stance from the storage chip 200 in the topmost layer to a logic chip 400 and the communication distance from the storage chip 200 in the bottommost layer to the logic chip, which results in a large difference among the communication delays of different storage chips 200 with the logic chip 400, thereby affecting the running speed of a product. In addition, both the packaging mode and power supply mode of the storage chip 200 may affect the performance of the semiconductor structure.

Embodiments of the disclosure provide a semiconductor structure, in which the plurality of storage chips are stacked in a direction parallel to the bottom surface of a groove of the substrate, so that the communication distances between the plurality of the storage chips and the logic chip are same, thereby contributing to unifying the communication delays and improving the running speed. In addition, a conductive part is connected between a power supply wiring layer and a power supply pin, so that wired power supply to the storage chips is realized, and the reliability is higher. In addition, the storage module is buried in the substrate, thereby contributing to improving the stability of the structure.

The embodiments of the disclosure will be described below in detail in combination with the drawings. However, those of ordinary skill in the art would understand that many technical details are provided to better understand the disclosure in the embodiments of the disclosure. However, the technical solutions claimed in the embodiments of the disclosure can be implemented even without these technical details and various changes and modifications based on the following embodiments.

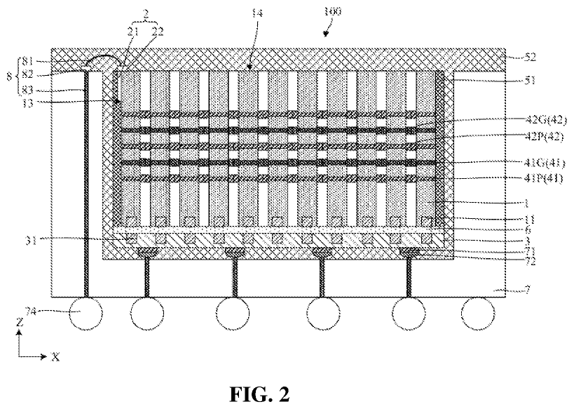

As shown in FIGS. 2-10, an embodiment of the disclosure provides a semiconductor structure. The semiconductor structure includes: a substrate 7 having a groove 14 and power supply pins 74; a storage module 100 located in the groove 14, in which the storage module 100 includes a plurality of storage chips 1 stacked in a first direction X, the first direction X being parallel to the bottom surface of the groove 14, power supply signal lines 12 being provided in each of the storage chips 1, and at least one of the plurality of storage chips 1 has a power supply wiring layer 2 electrically connected to the power supply signal lines 12; and conductive parts 8 connected with the power supply wiring layer 2 and the power supply pins 74.

Such design includes at least the following effects.

First, the plurality of storage chips 1 are stacked in a direction parallel to the bottom surface of the groove 14, namely, the arrangement direction of the plurality of storage chips 1 is parallel to the bottom surface of the groove 14. That is to say, the side surface of the storage chip 1 faces the groove 14. Because the area of the side surface is small, the occupied space of the bottom surface of the groove 14 thereby is small, and thus the groove 14 can accommodate more storage chips 1, thereby increasing the storage capacity. It is to be noted that surfaces of the storage chip 1 include a front surface and a back surface opposite to each other, and side surfaces connected between the front surface and the back surface, and the area of the front surface and the back surface is larger than that of the side surfaces.

Second, the storage module 100 is located in the groove 14, namely, the substrate 7 can surround the storage module 100, so that the stability of the storage module 100 is higher. In other words, even if the area of the storage chip 1 facing the bottom surface of the groove 14 is small, the groove 14 can limit the storage module 100, so that the strength and stability of the structure are higher.

Third, the power supply wiring layer 2 can lead out the power supply signal lines 12 from the edge position of the storage chip 1. Moreover, the power supply wiring layer 2 is electrically connected to the power supply pins 74 through the conductive parts 8, so that wired power supply to the storage chip 1 is realized, thereby improving the stability of current.

The semiconductor structure will be described in detail below in combination with the drawings.

First, it is to be noted that the semiconductor structure has a first direction X, a second direction Y, and a third direction Z therein. The first direction X is the stacking direction of the storage chip 1; the second direction Y is perpendicular to the first direction X and parallel to the upper surface of the logic chip 3, and the third direction Z is perpendicular to the upper surface of the logic chip 3.

Referring to FIGS. 2, 5 and 7, the plurality of storage chips 1 may be stacked by way of mixed bonding. For example, dielectric layers 43 are further provided on surfaces of the storage chips 1, and the dielectric layers 43 of adjacent storage chips 1 may be connected together by means of an action force such as a molecular force. Besides, bonding parts 42 are further provided on surfaces of the storage chips 1. Under a temperature rise condition, adjacent bonding parts 42 are bonded and connected together. That is to say, the dielectric layer 43 is made from an insulating material, which can play an isolation role; and the bonding part 42 is made from a conductive material, which can play an electrical connection role.

The storage chip 1 may be a chip such as a Dynamic Random Access Memory (DRAM) or a Static Random-Access Memory (SRAM). In some embodiments, the stacking modes of adjacent storage chips 1 all may be front surface to back surface, thereby contributing to unifying the bonding steps of the storage chips 1, so that the production process is simpler. In some embodiments, the stacking modes of adjacent storage chips 1 may also include front surface to front surface, or back surface to back surface. In an embodiment, the front surface of the storage chip 1 may be understood as an active surface 13, and the back surface may be understood as a non-active surface opposite to the active surface 13.

The power supply wiring layer 2 will be described in detail below.

Referring to FIGS. 2, 5 and 7, the side surface, far away from the bottom surface of the groove 14, of the power supply wiring layer 2 is exposed by the storage chip 1 and is connected to the conductive parts 8. That is to say, the power supply wiring layer 2 is led out from the upper side of the storage module 100. Since the upper side of the storage module 100 is exposed by the opening of the groove 14, it is simpler to lead out the power supply wiring layer 2 from the upper side of the storage module 100, and the conductive parts 8 can be flexibly disposed.

The power supply wiring layer 2 includes a first wiring layer 21 and a second wiring layer 22 connected with each other. The first wiring layer 21 extends on the surface, perpendicular to the bottom surface of the groove 14, of the storage chip 1, the second wiring layer 22 extends on the surface, parallel to the bottom surface of the groove 14, of the storage chip 1, and the second wiring layer 22 is connected to the conductive parts 8. The width of the second wiring layer 22 in the first direction X is larger than the width of the first wiring layer 21 in the first direction X. That is, the first wiring layer 21 is located inside the storage module 100, and the second wiring layer 22 is located on the surface, far away from the bottom surface of the groove 14, of the storage chip 1, so as to be exposed by the storage module 100.

Referring to FIGS. 2, 5 and 7, the first wiring layer 21 may be located on the front surface of the storage chip 1, i.e., extending along the active surface 13 of the storage chip 1. Therefore, after elements in the storage chip 1 are manufactured, the first wiring layer 21 may be manufactured by using the original back-end process, such that the process is simpler. In addition, the first wiring layer 21 may extend only at the edge position close to a side of the active surface 13 of the storage chip 1 without covering the entire active surface 13 of the storage chip 1. Therefore, the contact area between the first wiring layer 21 and the storage chip 1 is small, reducing the influence of heat of the first wiring layer 21 on the storage chip 1.

The second wiring layer 22 may serve as a bonding pad 84 connecting the first wiring layer 21 and the conductive parts 8 to increase the welding area, reducing the welding difficulty, and reducing the contact resistance between the power supply wiring layer 2 and a lead 81.

In some embodiments, the width of the second wiring layer 22 in the first direction X is smaller than or equal to the width of storage chip 1 in the first direction X, thereby contributing to saving materials, reducing the production cost. In addition, in the first direction X, the width of the second wiring layer 22 may also be greater than half of the width of the storage chip 1, thereby ensuring a sufficient welding area between the conductive part and the second wiring layer 22.

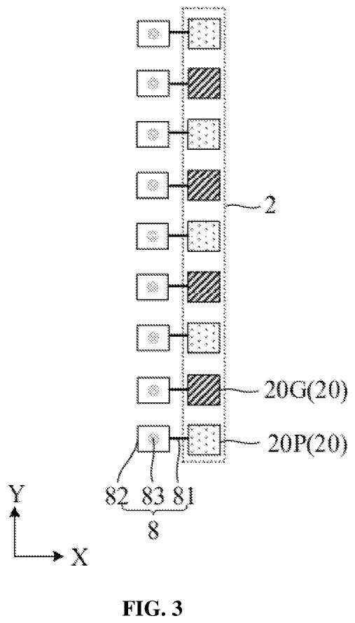

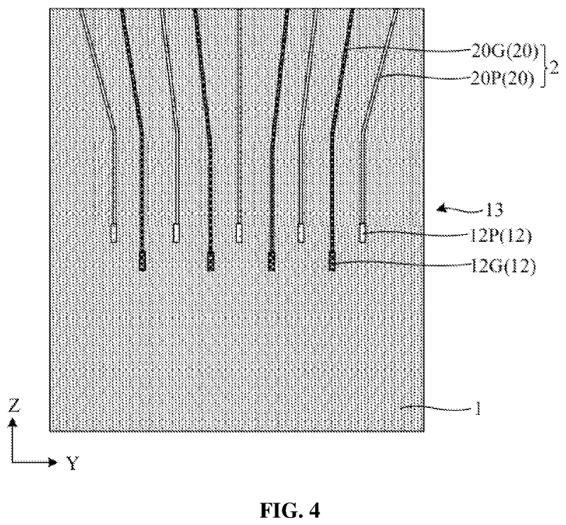

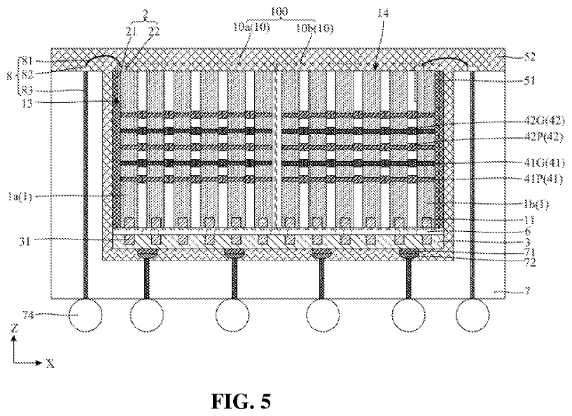

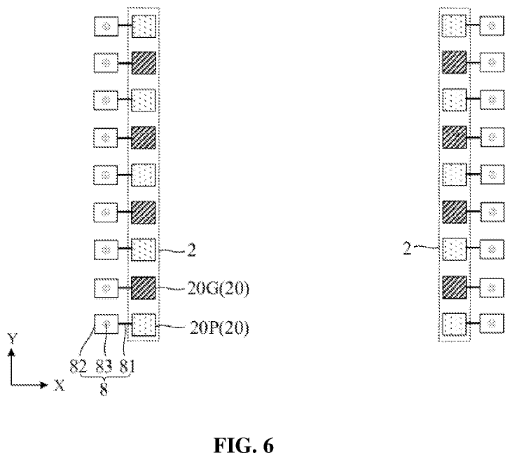

Referring to FIGS. 3-4, FIG. 6, and FIGS. 8-10, each power supply wiring layer 2 includes a plurality of power supply wires 20 disposed at intervals, and different power supply wires 20 have different voltage signals. Exemplarily, a plurality of power supply signal lines 12 of a same power supply wiring layer 2 are arranged at intervals in the second direction Y. The power supply wiring layer 2 includes ground wires 20G and power source wires 20P.

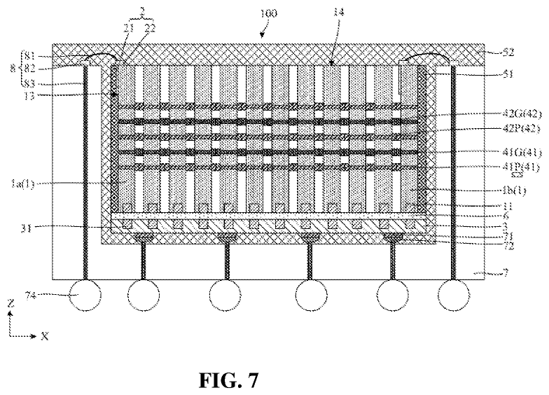

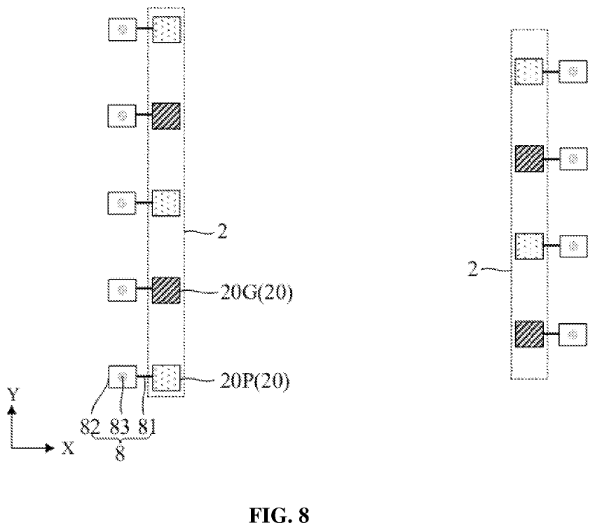

Referring to FIG. 4, FIG. 9, and FIG. 10, FIG. 4, FIG. 9, and FIG. 10 respectively illustrate schematic diagrams of active surfaces 13 of different storage chips 1. A plurality of power supply signal lines 12 are provided in each of the storage chips 1. The power supply signal lines 12 are led out of the active surfaces 13 from the storage chip 1 to be connected to the power supply wiring layer 2. Different power supply signal lines 12 have different voltage signals, so as to provide different voltage signals for elements in the storage chip 1, such as digital signals or analog signals. The power supply signal lines 12 may be ground signal lines 12G or power source signal lines 12P. Different ground signal lines 12G have different voltage signals, and different power source signal lines 12P have different voltage signals. One power supply wire 20 is electrically connected to one power supply signal line 12. Specifically, the ground wire 20G is electrically connected to the ground signal line 12G correspondingly, and the power source wire 20P is electrically connected to the power source signal line 12P correspondingly.

The conductive part 8 will be described in detail below.

Referring to FIG. 2, FIG. 5, and FIG. 7, the conductive part 8 includes a perforation 83 and a lead 81. The perforation 83 runs through the substrate 7 and is connected between the lead 81 and the power supply pin 74; and the lead 81 is connected to the power supply wiring layer 2. That is, the power supply pin 74 is located on the bottom surface of the substrate 7, and the lead 81 is located on the top surface of the substrate 7. The perforation 83 is located inside the substrate 7, so as to improve the space utilization. The lead 81 is easy to bend, so that the flexibility of connecting the conductive part 8 and the power supply wiring layer 2 can be improved.

In some embodiments, the conductive part 8 further includes a switching layer 82. The switching layer 82 is located on the upper surface of the substrate 7 and is connected between the lead 81 and the perforation 83. The width of the switching layer 82 in the first direction X is greater than the width of the perforation 83 in the first direction X. That is, the switching layer 82 can increase the welding area to simplify the welding between the lead 81 and the perforation 83. In some other embodiments, the switching layer 82 may also not be formed, and the lead 81 is directly connected with the perforation 83.

It is to be noted that the second wiring layer 22 may be formed in the same process step as the switching layer 82, thereby reducing the process steps and thus the production cost.

Referring to FIG. 3, FIG. 6, and FIG. 8, a plurality of conductive parts 8 are provided, and one conductive part 8 is connected with one power supply wire 20, thus providing different voltage signals for the storage chip 1. That is, one power supply wiring layer 2 is connected with a plurality of conductive parts 8. In some embodiments, a plurality of conductive parts 8 connected with a same power supply wiring layer 2 may be arranged at intervals in the second direction Y, and the plurality of conductive parts 8 may be disposed in one-to-one correspondence with the power supply wires 20 in the first direction X, so that the connection process between the two is simpler.

For example, the switching layers 82 electrically connected to a same power supply wiring layer 2 may be arranged in a straight line in the second direction Y, and correspondingly, the perforations 83 electrically connected to the same power supply wiring layer 2 may be arranged in a straight line in the second direction Y, which is conducive to improving the uniformity of the semiconductor structure and saving space. In some other embodiments, the switching layers 82 electrically connected to the same power supply wiring layer 2 may be slightly staggered in the second direction Y, and the perforations 83 electrically connected to the same power supply wiring layer 2 may be slightly staggered in the second direction Y, so that the distances between adjacent switching layers 82 and adjacent perforations 83 can be increased to avoid incorrect electrical connection.

The quantity of the power supply wiring layer 2 and the relative position relationship between the power supply wiring layer 2 and the conductive part 8 will be described in detail below.

First, it is to be noted that in a case where one storage chip 1 itself has a power supply wiring layer 2, at least part of the power supply signal lines 12 of the storage chip 1 may be directly connected to its own power supply wiring layer 2, i.e., led out by its own power supply wiring layer 2. In a case where one storage chip 1 itself does not have a power supply wiring layer 2, the power supply signal lines 12 of the storage chip 1 may be led out by means of the power supply wiring layer 2 of other storage chip 1. In other words, an electric connection relation may be established between the storage chip 1 and the other storage chip 1 by means of the conductive through holes 41 and the bonding parts 42, so that its own power supply signal lines 12 are electrically connected to the power supply signal lines 12 of the other storage chip 1, so as to be further electrically connected to the power supply wiring layer 2 of the other storage chip 1.

In some embodiments, referring to FIG. 2, FIG. 5, and FIG. 7, at least one of the storage chips 1 at both the head and tail sides of the storage module 100 has a power supply wiring layer 2. That is, at least one of the storage chips 1 at both outermost sides of the storage module 100 has a power supply wiring layer 2. Conductive through holes 41 are provided in the storage chip 1, and the conductive through holes 41 are electrically connected with the power supply signal lines 12. Bonding parts 42 are provided between adjacent storage chips 1, and the bonding parts 42 are connected with the conductive through holes 41. The power supply signal lines 12 of the plurality of storage chips 1 are electrically connected through the conductive through holes 41 and the bonding parts 42.

Compared with that the power supply wiring layer 2 is located on the storage chip 1 at the intermediate of the storage module 100, that the power supply wiring layer 2 is located on the storage chip 1 at the outermost side of the storage module 100 is beneficial for reducing the length of conductive part 8 to reduce power consumption and reducing the height of the whole package in the third direction Z.

In example I, referring to FIGS. 2-4, FIG. 2 is a sectional view, FIG. 3 is a top view of a semiconductor structure shown in FIG. 2, and only the conductive parts 8 and the power supply wiring layer 2 are shown in FIG. 3 in order to be more intuitive, and FIG. 4 illustrates an active surface 13 of a storage chip 1 with a power supply wiring layer 2 in FIG. 2. At least one of the storage chips 1 at both the head and tail sides of the storage module 100 has a power supply wiring layer 2, and the power supply signal lines 12 of all the storage chips 1 are electrically connected with the power supply wiring layer 2.

That is to say, the power supply signal lines 12 with a same voltage signal in all the storage chips 1 are electrically connected through the conductive through holes 41 and the bonding parts 42, and are led out through the power supply wiring layer 2 of one storage chip 1 at an outermost side of the storage module 100. Exemplarily, the conductive through holes 41 include power source through holes 41P and ground through holes 41G, and the bonding parts 42 include power source bonding parts 42P and ground bonding parts 42G. The power source through holes 41P are connected with the power source bonding parts 42P, and the ground through holes 41G are connected with the ground bonding parts 42G. The quantity of the power supply wiring layer 2 is small, so that the connecting process of the power supply wiring layer 2 and the conductive parts 8 can be simplified.

In some embodiments, all power supply pins 74 are located on a same side of the storage module 100 and are arranged adjacent to the storage chip 1 with the power supply wiring layer 2, and accordingly, all the conductive parts 8 are located on the same side of the storage module 100, thus shortening the length of the conductive part 8 to reduce power consumption. For example, the power supply pins 74 and the storage chips 1 are arranged in the first direction X, and a plurality of power supply pins 74 are arranged in a straight line in the second direction Y

In example II, referring to FIGS. 5-10, the storage chips 1 at both the head and tail sides of the storage module 100 each have a power supply wiring layer 2. That is to say, the power supply signal lines 12 may be led out from both outermost sides of the storage module 100. Compared with that the power supply signal lines 12 are led out from one side of the storage module 100, that the power supply signal lines 12 are led out from both sides can provide more lead-out positions, thus improving the reliability of power supply.

Exemplarily, the power supply pins 74 are divided into two groups. The power supply pins 74 in each group are close to the storage chips 1 on both the head and tail side and connected to two power supply wiring layers 2 respectively.

FIG. 5 is a sectional view. FIG. 6 is a top view of a semiconductor structure shown in FIG. 5, and only the conductive parts 8 and the power supply wiring layer 2 are shown in FIG. 6. The schematic diagrams of active surfaces 13 of the storage chips 1 at the both outermost sides in FIG. 5 are the same as that in FIG. 4. Referring to FIGS. 4-6, in some embodiments, the storage module 100 includes two chip groups 10 arranged in the first direction X, and each chip group 10 includes a plurality of storage chips 1. Power supply signal lines 12 of a same chip group 10 are electrically connected to the power supply wiring layer 2 nearest thereto.

For example, the storage module 100 includes a first chip group 10a and a second chip group 10b. All power supply signal lines 12 of the first storage chip 1a can be directly electrically connected to the power supply wiring layer 2 on the surface of the first storage chip 1a, and the power supply signal lines 12 of other storage chips 1 in the first chip group 10a are electrically connected to the power supply signal lines 12 of the first storage chip 1a through bonding parts 42 and conductive through holes 41, so that all power supply signal lines 12 of the first chip group 10a can be led out from the power supply wiring layer 2 on the surface of the first storage chip 1a. In a similar way, all power supply signal lines 12 of the second storage chip 1b can be directly electrically connected to the power supply wiring layer 2 on the surface of the second storage chip 1b, and the power supply signal lines 12 of other storage chips 1 in the second chip group 10b are electrically connected to the power supply signal lines 12 of the second storage chip 1b through bonding parts 42 and conductive through holes 41, so that all power supply signal lines 12 of the second chip group 10b can be led out from the power supply wiring layer 2 on the surface of the second storage chip 1b. The power supply signal lines 12 of the two chip groups 10 are led out separately, which is conductive to improving the stability and reliability of power supply.

FIG. 7 is a sectional view. FIG. 8 is a top view of a semiconductor structure shown in FIG. 7, and only the conductive parts 8 and the power supply wiring layer 2 are shown in FIG. 8. FIG. 9 and FIG. 10 respectively are the schematic diagrams of active surfaces 13 of the storage chips 1 at the both outermost sides as shown in FIG. 7. Referring to FIGS. 7-10, in some other embodiments, each storage chip 1 has a first power supply signal line group 121 and a second power supply signal line group 122, and each of the first power supply signal line group 121 and the second power supply signal line group 122 includes a plurality of power supply signal lines 12. All the first power supply signal line groups 121 are electrically connected to a power supply wiring layer 2; and all the second power supply signal line groups 122 are electrically connected to the other power supply wiring layer 2.

For example, the storage chips 1 at the both outermost sides are a first storage chip 1a and a second storage chip 1b respectively. The first power supply signal line group 121 of the first storage chip 1a is directly connected to the power supply wiring layer 2 on the surface of the first storage chip 1a, and the first power supply signal line groups 121 of storage chips 1 except the first storage chip 1a are electrically connected to the first power supply signal line group 121 of the first storage chip 1a through bonding parts 42 and conductive through holes 41, so that all the first power supply signal line groups 121 can be guided out from the power supply wiring layer 2 on the surface of the first storage chip 1a. In a similar way, the second power supply signal line group 122 of the second storage chip 1b is directly connected to the power supply wiring layer 2 on the surface of the second storage chip 1b, and the second power supply signal line groups 122 of storage chips 1 except the second storage chip 1b are electrically connected to the second power supply signal line group 122 of the second storage chip 1b through bonding parts 42 and conductive through holes 41, so that all the second power supply signal line groups 122 can be guided out from the power supply wiring layer 2 on the surface of the second storage chip 1b.

That is to say, the first signal line groups 121 and the second signal line groups 122 are respectively led out from two sides of the storage module 100. In this way, it is facilitated that more sufficient connection positions are provided for the leads 81, so as to increase the distance between adjacent leads 81 and thus avoid incorrect electrical connection.

Referring to FIGS. 2, 5 and 7, the semiconductor structure further includes: a logic chip 3 located between the bottom surface of the groove 14 and the storage module 100. First wireless communication parts 11 are provided in the storage chips 1. Second wireless communication parts 31 are provided in the logic chip 3. The first wireless communication parts 11 are in wireless communication with the second wireless communication parts 31.

The distances between the plurality of the storage chips 1 and the logic chip 3 are the same, so that the wireless communication delays of the plurality of the storage chips 1 with the logic chip 3 are consistent. In some embodiments, the first wireless communication parts 11 are located in the sides, facing the logic chip 3, of the storage chips 1. Therefore, the distance between the first wireless communication parts 11 and the second wireless communication parts 31 can be reduced, so as to improve the quality of wireless communication.

It is to be noted that if the arrangement direction of the plurality of storage chips 1 is perpendicular to the upper surface of the logic chip 3, there is a large difference among the communication delays of storage chips 1 in different layers with the logic chip 3. In addition, as the number of layers increases, the number of Through-Silicon Vias (TSVS) for communication increases proportionally, thus sacrificing the wafer area. In the embodiments of the disclosure, the stacking direction and communication mode of the storage chips 1 are changed, which is conducive to improving the communication quality and can also save the wafer area.

Referring to FIGS. 2, 5 and 7, a side surface of the storage chip 1 is disposed towards the logic chip 3, and the area of the side surface is small. In the wireless communication mode, there is no need to dispose a wired communication part between the storage chips 1 and the logic chip 3, so that the technical difficulty can be reduced, and sufficient space can also be provided for the connection structure between the storage chips 1 and the logic chip 3 to improve the structural strengths of the two. In addition, the lower side of the storage module 100 is configured for wireless communication, and the upper side of the storage module 100 is configured for laying out a wired power supply path, so that electromagnetic interference caused by the current in the wired power supply path to coils in the wireless communication parts can be reduced, thus avoiding signal loss.

In some embodiments, an attach layer 6 is further provided between the storage module 100 and the logic chip 3. That is, the storage module 100 and the logic chip 3 are connected together by gluing, thus forming a memory core. Exemplarily, the attach layer 6 may be a Die Attach Film (DAF). The attach process is relatively simple, which can save cost. In addition, the attach layer 6 may also be doped with metal ions to improve the heat dissipation effect of the storage module 100 and the logic chip 3. In some other embodiments, a welding layer (not shown in the figure) may be provided between the storage module 100 and the logic chip 3, that is, the storage module 100 and the logic chip 3 are connected together by welding.

Referring to FIGS. 2, 5 and 7, welding bumps 71 and solder layers 72 are further provided between the logic chip 3 and the substrate 7, that is, the logic chip 3 is welded to the bottom surface of groove 14 by flip welding. In this way, the substrate 7 can supply power and exchange signals to the logic chip 3 in a wired mode which has higher reliability.

In some embodiments, the material of the substrate 7 may be selected from materials with excellent heat dissipation performance to enhance the heat dissipation of the storage module 100 and the logic chip 3. For example, the material of the substrate 7 may be organic material, ceramic, glass, etc.

Referring to FIGS. 2, 5 and 7, the semiconductor structure further includes: a first sealing layer 51 surrounding the storage module 100 and exposing the side surfaces, far away from the bottom surface of the groove 14, of the storage chips 1 and the first wiring layer 21. The first sealing layer 51 can protect the storage module 100 from external environment, such as external moisture, solvents, and thermal shock and mechanical vibration during installation of the semiconductor structure.

The semiconductor structure further includes: a second sealing layer 52 covering the second wiring layer 22 and at least part of a conductive part 8. Exemplarily, the second sealing layer 52 covers the inner wall of the groove 14 and the top surface of the substrate 7, that is, covering the storage module 100, the leads 81, the second wiring layer 22, the switching layers 82, the first sealing layer 51, the welding bumps 71 and the solder layers 72. The second sealing layer 52 can improve the protection and isolation effect to ensure the performance of the semiconductor structure.

In an embodiment, the materials of the first sealing layer 51 and the second sealing layer 52 may be the same, for example, the first sealing layer 51 and the second sealing layer 52 may be epoxy resins.

In an embodiment, the materials of the first sealing layer 51 and the second sealing layer 52 may be different, for example, the thermal conductivity of the second sealing layer 52 is higher than that of the first sealing layer 51. Through this arrangement, heat introduced into the second sealing layer 52 through the lead 81 can be transferred to the external environment faster, reducing the adverse impact of the high temperature environment on the storage module 100.

To sum up, in the embodiments of the disclosure, the arrangement direction of the plurality of storage chips 1 is parallel to the bottom surface of the groove 14, so that the groove 14 may accommodate more storage chips 1, thereby increasing the storage capacity. In addition, the groove 14 can limit the storage module 100 to avoid the toppling of the storage module 100. In addition, the power supply wiring layer 2 is led out from the opening of groove 14, which enables a more simple and flexible layout of the wired power supply path.

As shown in FIGS. 10-11 and FIG. 2, another embodiment of the disclosure provides a method for manufacturing a semiconductor structure, with which the semiconductor structure provided by the foregoing embodiment can be manufactured. For the detailed description of the semiconductor structure, reference is made to the foregoing embodiment.

Specifically, referring to FIG. 10, a storage module 100 is provided. The storage module 100 includes a plurality of storage chips 1 stacked in a first direction X. Power supply signal lines 12 are provided in each of the storage chips 1. At least one of the plurality of storage chips 1 has a power supply wiring layer 2. The power supply wiring layer 2 is electrically connected to the power supply signal lines 12.

For example, a plurality of storage chips 1 are provided; and then a first wiring layer 21 is formed by Fan-out Wafer Level Packaging (FOWLP), and thus the power supply signal lines 12 are led to a side of the storage module 100. After the first wiring layer 21 is formed, the plurality of storage chips 1 are stacked. Exemplarily, the power supply signal lines 12 of each layer of storage chip 1 are guided out to the storage chip 1 at an outermost side through conductive through holes 41 and bonding parts 42, and then led out to the edge of the storage chip 1 through a first wiring layer 21 processed on the outermost side. It is to be noted that the storage chips 1 are placed horizontally during bonding.

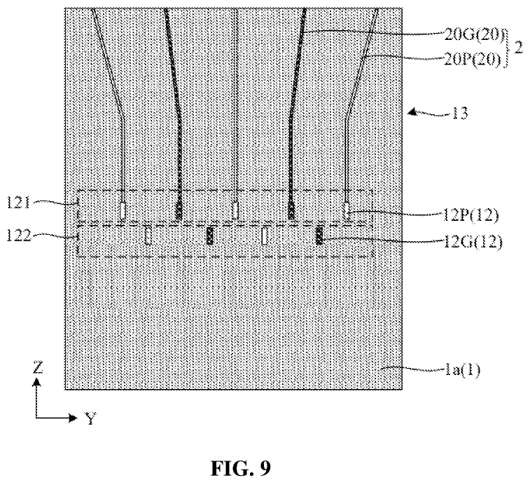

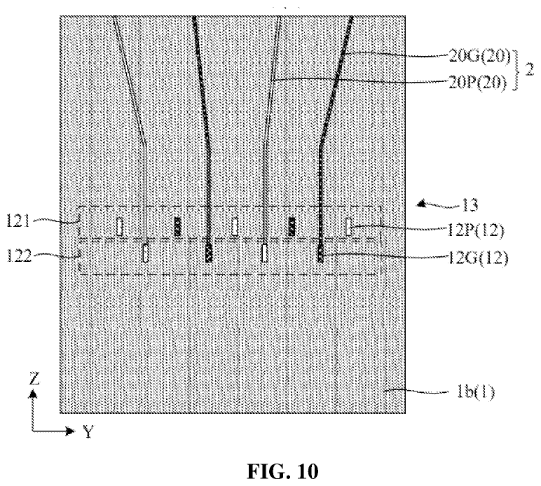

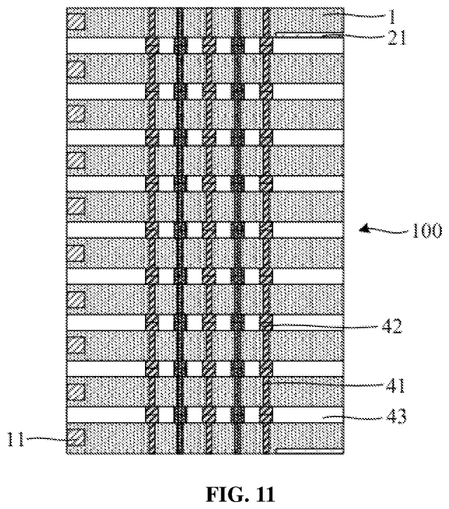

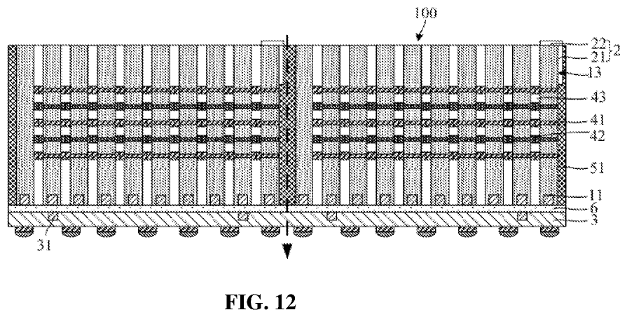

Referring to FIG. 11, a first molding process is carried out on the storage module 100 to form a first sealing layer 51 around the storage module 100. The first sealing layer 51 also exposes the side surfaces of the storage chips 1 and part of the surface of the first wiring layer 21. After the first molding process, a second wiring layer 22 is formed on the side surface of the storage chip 1. The second wiring layer 22 is connected with the first wiring layer 21.

Exemplarily, the storage module 100 is rotated by 90° so that each storage chip 1 is perpendicular to the logic chip 3, and the storage chips 1 and the logic chip 3 are fixed through a DAF; a plurality of storage modules 100 are reconstructed through the first molding process to form a reconstructed wafer; and the second wiring layers 22 and switching layers 82 are deposited on the top surface of the reconstructed wafer by a rewiring process. The reconstructed wafer is scribed to form memory cores. Each memory core includes one storage module 100 and one logic chip 3.

Referring to FIG. 2, a substrate 7 is provided, the substrate 7 having a groove 14 and power supply pins 74; a storage module 100 is placed in the groove 14, and the first direction X is enabled to be parallel to the bottom surface of the groove 14; and a power supply wiring layer 2 is connected to the power supply pins 74 through conductive parts 8.

Exemplarily, the memory cores are buried in groove 14, and are welded to the bottom surface of the groove 14 by flip welding. Power supply wires 20 are connected to a corresponding switching layer 82 respectively through leads 81, so as to realize connection of power supply signals between the storage chips 1 and the substrate 7. Then, a second sealing layer 52 is formed through a second molding process.

It is to be noted that the reason for adopting two molding processes successively is that the first molding process can connect a plurality of storage modules 100 together, therefore, second wiring layers 22 can be formed subsequently on the plurality of storage modules 100 at the same time, which is conducive to reducing the process steps. In addition, the volume of a single storage module 100 is small, while the total volume is larger after a plurality of storage modules 100 are connected together, so that the stability is higher, and thus toppling seldom occurs. In addition, the first sealing layer 51 formed by the first molding process can protect and fix the storage modules 100 during the subsequent steps including formation of the second wiring layers 22 and flip welding to prevent the storage modules 100 from collapsing or being damaged, thus ensuring the performance of the storage modules 100. In addition, two successive molding processes can improve the sealing effect.

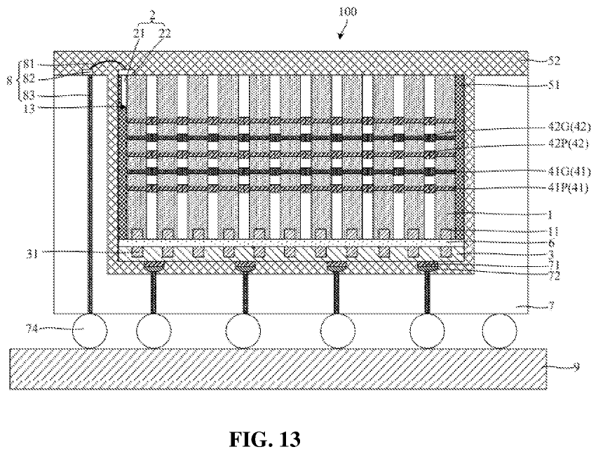

As shown in FIG. 13, still another embodiment of the disclosure provides a semiconductor device, which may include the semiconductor structure in the foregoing embodiment. For the detailed description of the semiconductor structure, reference is made to the foregoing embodiment.

The semiconductor device includes: a circuit board 9; a substrate 7 having a groove 14 and power supply pins 74, the substrate 7 being disposed on the circuit board 9; a storage module 100 located in the groove 14, in which the storage module 100 includes a plurality of storage chips 1 stacked in a first direction X, the first direction X being parallel to the bottom surface of the groove 14, power supply signal lines 12 being provided in each of the storage chips 1, and at least one of the plurality of storage chips 1 having a power supply wiring layer 2, the power supply wiring layer 2 being electrically connected to the power supply signal lines 12; and conductive parts 8 connected with the power supply wiring layer 2 and the power supply pins 74.

Exemplarily, the substrate 7 is connected to the external circuit board 9 through a ball grid array, a power source may be disposed on the circuit board 9, and the power supply pins 74 are electrically connected to the power source on the circuit board 9, so as to supply power to the storage module 100.

In the descriptions of the specification, the descriptions made with reference to the terms “some embodiments”, “exemplarily”, and the like refer to that specific features, structures, materials or characteristics described in combination with the embodiments or the examples are included in at least one embodiment or example of the disclosure. In the specification, these terms are not always schematically expressed for the same embodiment or example. Moreover, the specific described features, structures, materials or characteristics may be combined in a proper manner in any one or more embodiments or examples. In addition, those skilled in the art would integrate and combine different embodiments or examples described in the specification and features of different embodiments or examples without conflicts.

The embodiments of the disclosure have been shown or described above, however, it can be understood that the abovementioned embodiments are exemplary and should not be understood as limits to the disclosure. Those of ordinary skill in the art may make changes, modifications, replacements and variations to the abovementioned embodiments within the scope of the disclosure, it is therefore intended that all changes or modifications made in light of the claims and specification of the disclosure shall fall within the scope of the disclosure.

1. A semiconductor structure, comprising:
a substrate having a groove and power supply pins;
a storage module located in the groove; wherein the storage module comprises a plurality of storage chips stacked in a first direction, wherein the first direction is parallel to a bottom surface of the groove; power supply signal lines are provided in each of the storage chips, and at least one of the plurality of storage chips has a power supply wiring layer electrically connected to the power supply signal lines; and
conductive parts connected with the power supply wiring layer and the power supply pins.

2. The semiconductor structure of claim 1, wherein a side surface, far away from the bottom surface of the groove, of the power supply wiring layer is exposed by the at least one of the storage chips and is connected to the conductive parts.

3. The semiconductor structure of claim 2, wherein the power supply wiring layer comprises a first wiring layer and a second wiring layer connected with each other, wherein the first wiring layer extends on a surface, perpendicular to the bottom surface of the groove, of the at least one of the storage chips, and the second wiring layer is located on a surface, far away from the bottom surface of the groove, of the at least one of the storage chips, and is connected to the conductive parts;
wherein a width of the second wiring layer in the first direction is larger than a width of the first wiring layer in the first direction.

4. The semiconductor structure of claim 3, wherein the width of the second wiring layer in the first direction is smaller than or equal to a width of the at least one of the storage chips in the first direction.

5. The semiconductor structure of claim 3, further comprising:
a first sealing layer surrounding the storage module and exposing side surfaces, far away from the bottom surface of the groove, of the storage chips and the first wiring layer; and
a second sealing layer covering the second wiring layer and at least part of a conductive part.

6. The semiconductor structure of claim 1, wherein
at least one of the storage chips at both head and tail sides of the storage module has the power supply wiring layer;
conductive through holes are provided in the storage chips, wherein the conductive through holes are electrically connected with the power supply signal lines; and bonding layers are provided between adjacent storage chips, wherein the bonding layers are connected with the conductive through holes; and
the power supply signal lines of the plurality of storage chips are electrically connected with the power supply wiring layer through the conductive through holes and the bonding layers.

7. The semiconductor structure of claim 6, wherein
the at least one of the storage chips at both the head and tail sides of the storage module has the power supply wiring layer; the power supply pins are located on a same side of the storage module and are disposed adjacent to the at least one of the storage chips with the power supply wiring layer; and
the power supply signal lines of all the storage chips are electrically connected with the power supply wiring layer.

8. The semiconductor structure of claim 6, wherein
each of the storage chips at both the head and tail sides of the storage module has the power supply wiring layer;
the storage module comprises two chip groups arranged in the first direction, wherein each chip group comprises a plurality of storage chips; and
power supply signal lines of a same chip group are electrically connected to the power supply wiring layer nearest to the chip group.

9. The semiconductor structure of claim 6, wherein
each of the storage chips at both the head and tail sides of the storage module has a power supply wiring layer;
each of all the storage chips comprises a first power supply signal line group and a second power supply signal line group, wherein each of the first power supply signal line group and the second power supply signal line group comprises a plurality of power supply signal lines; and
first power supply signal line groups of all the storage chips are electrically connected to one power supply wiring layer; and second power supply signal line groups of all the storage chips are electrically connected to another power supply wiring layer.

10. The semiconductor structure of claim 1, wherein
each of the conductive parts comprises a perforation and a lead; wherein the perforation runs through the substrate and is connected between the lead and a corresponding one of the power supply pins; and the lead is connected to the power supply wiring layer.

11. The semiconductor structure of claim 10, wherein
each of the conductive parts further comprises a switching layer, wherein the switching layer is located on an upper surface of the substrate and is connected between the lead and the perforation; and
a width of the switching layer in the first direction is greater than a width of the perforation in the first direction.

12. The semiconductor structure of claim 1, wherein
the power supply wiring layer comprises a plurality of power source wires and a plurality of ground wires; and the power supply signal lines comprise a plurality of power source signal lines and a plurality of ground signal lines; wherein the power source wires are electrically connected with the power source signal lines, and the ground wires are electrically connected with the ground signal lines; and
the power source wires and the ground wires are arranged alternately in a second direction, wherein the second direction is perpendicular to the first direction and parallel to the bottom surface of the groove.

13. The semiconductor structure of claim 1, further comprising:
a logic chip located between the bottom surface of the groove and the storage module;
wherein first wireless communication parts are provided in the storage chips; and
second wireless communication parts are provided in the logic chip;
wherein the first wireless communication parts are in wireless communication with the second wireless communication parts.

14. The semiconductor structure of claim 13, wherein an attach layer or a welding layer is further provided between the logic chip and the storage module.

15. A method for manufacturing a semiconductor structure, comprising:
providing a substrate having a groove and power supply pins;
providing a storage module, wherein the storage module comprises a plurality of storage chips stacked in a first direction; wherein power supply signal lines are provided in each of the storage chips, and at least one of the plurality of storage chips has a power supply wiring layer electrically connected to the power supply signal lines;
placing the storage module in the groove, and enabling the first direction to be parallel to a bottom surface of the groove; and
connecting the power supply wiring layer with the power supply pins through conductive parts.

16. The method for manufacturing the semiconductor structure of claim 15, wherein
providing the storage module comprises:
providing a plurality of storage chips;
forming a first power supply wiring layer on at least one of the plurality of storage chips; and
after forming the first power supply wiring layer, stacking the plurality of storage chips; and
the method further comprises: before packaging the storage module in the groove,
carrying out a first molding process on the storage module to form a first sealing layer surrounding the storage module, wherein the first sealing layer also exposes side surfaces, far away from the bottom surface of the groove, of the storage chips and the first power supply wiring layer; and
after the first molding process, forming a second power supply wiring layer on a side surface, far away from the bottom surface of the groove, the at least one of the storage chips, wherein the second power supply wiring layer is connected with the first power supply wiring layer;
wherein packaging the storage module in the groove comprises:
carrying out a second molding process to form a second sealing layer covering the second power supply wiring layer and at least part of a conductive part.

17. A semiconductor device, comprising:
a circuit board;
a substrate having a groove and power supply pins; wherein the substrate is disposed on the circuit board;
a storage module located in the groove; wherein the storage module comprises a plurality of storage chips stacked in a first direction, wherein the first direction is parallel to a bottom surface of the groove; power supply signal lines are provided in each of the storage chips, and at least one of the plurality of storage chips has a power supply wiring layer electrically connected to the power supply signal lines; and
conductive parts connected with the power supply wiring layer and the power supply pins.
